(19) United States
(12) Patent Application Publication
(10) Pub. No.: US 2003/0207531 A1
(43) Pub. Date: Nov. 6, 2003

(54) Method for forming polysilicon connected deep trench dram cell

(76) Inventor: Ta-Cheng Lin, Hsin-Chu City (TW)

Correspondence Address: POWELL, GOLDSTEIN, FRAZER & MURPHY LLP, P.O. Box 97223, Washington, DC, 20090-7223, US

(21) Appl. No.: 10/135,730

(22) Filed: May 1, 2002

(51) Int. Cl. H01L 21/8242; H01L 21/20

(52) U.S. Cl. 438/243; 438/386

(57) ABSTRACT

A method for forming polysilicon connected deep trench DRAM cell. The method at least includes the following steps. First of all, a substrate is provided. Then, a buried plate drives in the substrate. Then, a capacitor dielectric layer is formed to fill into a lower portion of the deep trench. Next, a dielectric collar layer is formed on a sidewall of the deep trench about the capacitor dielectric layer. Then, a selective growth polysilicon layer is formed to fill into the deep trench of the opening. Then, the shallow trench isolation structure is formed in sidewall of the deep trench. Next, a metal-oxide-semiconductor transistor is formed on the substrate. Next, a spacer is formed on sidewall of the metal-oxide semiconductor transistor. Finally, a polysilicon layer is formed on the metal-oxide-semiconductor transistor.

### BACKGROUND OF THE INVENTION

1. Field of the Invention

The present invention generally relates to the manufacturing of semiconductor integrated circuits, and more particularly to a method for forming the polysilicon connected deep trench DRAM cell.

2. Description of the Prior Art

As the minimum feature size and cell architecture, i.e., number of squares, are scaled down, robust design points for dynamic random access memory (DRAM) cells utilizing metal oxide semiconductor field effect transistors (MOSFETS) and deep trench storage capacitors (also referred to herein as trench capacitors) are increasingly difficult to achieve. Scalability of the planar MOSFET in this environment is severely limited by the overlay tolerance between the wordline gate conductor, i.e., gate conductor, and the trench storage capacitor. This overlay sensitivity is exacerbated by the extent of the buried-strap out diffusion.

One manifestation of the scalability difficulties of planar DRAM MOSFETs is degradation of the retention time tail, due to increased junction leakage resulting from very high channel doping concentrations required to suppress short-channel effects. These short channel effects (often referred to as drain induced barrier lowering (DIBL)) are greatly amplified by the encroachment of the deep-strap out diffusion upon the array MOSFET. Because of the overlay variation between the wordline gate conductor and the deep storage trench, the distance between the edge of the buried-strap out diffusion and the edge of the wordline gate conductor may typically vary by as much as ±30-50% of the design distance.

To guard against excessive off-current when the buried strap is close to the array MOSFET, the channel doping concentration of the array MOSFET must be elevated to levels which result in increased junction leakage. Increased junction leakage is a defect mechanism activated by the increased electrical fields associated with high channel doping. It is thus essential that the overlay variation between the wordline gate conductor and the deep storage trench be very tightly controlled.

FIG. 1 illustrates a top view of a semiconductor substrate under fabrication as a deep trench DRAM cell in the prior art. The top view comprises a deep trench cell 100 and a bit line 102. The conventional deep trench DRAM cell easily causes a drain induced barrier lowering (DIBL) phenomenon.

Referring to FIG. 2, a substrate 100 is provided. A deep trench is formed in the substrate 100. The deep trench capacitor is formed at the lower portion of the deep trench. A capacitor dielectric layer 102 is formed on a sidewall of the deep trench at the portion below the capacitor. The capacitor dielectric layer 102 includes, for example, an oxide/nitride/oxide (O/N/O) dielectric layer or an oxide/nitride (O/N) dielectric layer. An oxide collar 104 is formed on a sidewall of the deep trench at the portion above the capacitor. The deep trench capacitor includes a buried plate 106 diffused into the substrate 100. A polysilicon layer 108 fills into the deep trench. The polysilicon layer 108 includes a lower portion between the oxide collar 104 and an upper portion that has a contact to the deep trench. Moreover, the polysilicon layer 108 is also implanted with dopants. The dopants of the polysilicon layer 108 can diffuse into the substrate surface to form a diffusion extension region 114 by a thermal process. The diffusion extension region 114 is used for a connection to a source/drain region of metal-oxide-semiconductor (MOS) transistors formed later. At this stage, the trench capacitor is electrically coupled to the subsequently formed device through the polysilicon layer 108 and the diffusion extension region 114. However, the adjacent two trench capacitors are necessary to be isolated, usually, by a shallow trench isolation (STI) 110 structure. Formation of the opening conventionally needs another photolithography and etching process. This needs an additional fabrication of photomask and the associated photoresist layer. Then, a n+ buried strap 112 is formed on a sidewall of the deep trench at the portion above the capacitor. The MOS transistors 20 are then formed, wherein the MOS transistors 20 have a gate oxide layer 116 on the substrate 100, a polysilicon layer 118 on the gate oxide layer 116, a conduction layer 120 on the polysilicon layer 118 and a silicon nitride layer 122 on the conduction layer 120. Then, a spacer 124 is formed on sidewall of the MOS transistors 20.

The conventional polysilicon connect to deep trench DRAM cell through a n+ buried strap has the following defects. The n+ buried strap 112 is very deep and the concentration n+ buried strap 112 is very dense to cause drain induced barrier lowering (DIBL) phenomenon. The polysilicon is out growth to generate crack and to cause variable refresh time (VRT) between the n+ buried strap and the polysilicon. A silicon nitride layer is formed to prevent variable refresh time (VRT) between the n+ buried strap and the polysilicon but the silicon nitride layer cause resistance increased.

For the forgoing drawbacks, there is a necessity for a method for forming polysilicon connected deep trench DRAM cell.

### SUMMARY OF THE INVENTION

In accordance with the present invention, the invention is to provide a method for forming polysilicon connected deep trench DRAM cell that provides polysilicon interconnect layout for deep trench DRAM cell operation.

One object of the present invention is to provide a method for forming polysilicon connected deep trench DRAM cell to provide polysilicon interconnect layout for deep trench DRAM cell operation.

In order to achieve the above object, the present invention provides a method for forming polysilicon connected deep trench DRAM cell. First of all, a substrate is provided. Then, a buried plate drives in the substrate. Then, a capacitor dielectric layer is formed to fill into a lower portion of the deep trench. Next, a dielectric collar layer is formed on a sidewall of the deep trench about the capacitor dielectric layer. Then, a selective growth polysilicon layer is formed to fill into the deep trench of the opening. Then, the shallow trench isolation structure is formed in sidewall of the deep trench. Next, a metal-oxide-semiconductor transistor is formed on the substrate. Next, a spacer is formed on sidewall of the metal-oxide-semiconductor transistor. Finally, a n+ polysilicon layer is formed on the metal-oxide-semiconductor transistor.

### BRIEF DESCRIPTION OF THE DRAWINGS

The foregoing aspects and many of the attendant advantages of this invention will become more readily appreciated as the same becomes better understood by referring to the following detailed description, when taken in conjunction with the accompanying drawings, wherein:

FIG. 1 illustrates a top view of a semiconductor substrate under fabrication as a deep trench DRAM cell in the prior art;

FIG. 2 is cross-sectional schematic diagrams illustrating polysilicon connected deep trench DRAM cell in the prior art;

FIG. 3 illustrates a top view of a semiconductor substrate under fabrication as a deep trench DRAM cell in the invention;

FIG. 4 is cross-sectional schematic diagrams illustrating polysilicon connected deep trench DRAM cell in the invention; and

FIGS. 5A-5D are cross-sectional schematic diagrams illustrating polysilicon connected deep trench DRAM cell in accordance with the present invention.

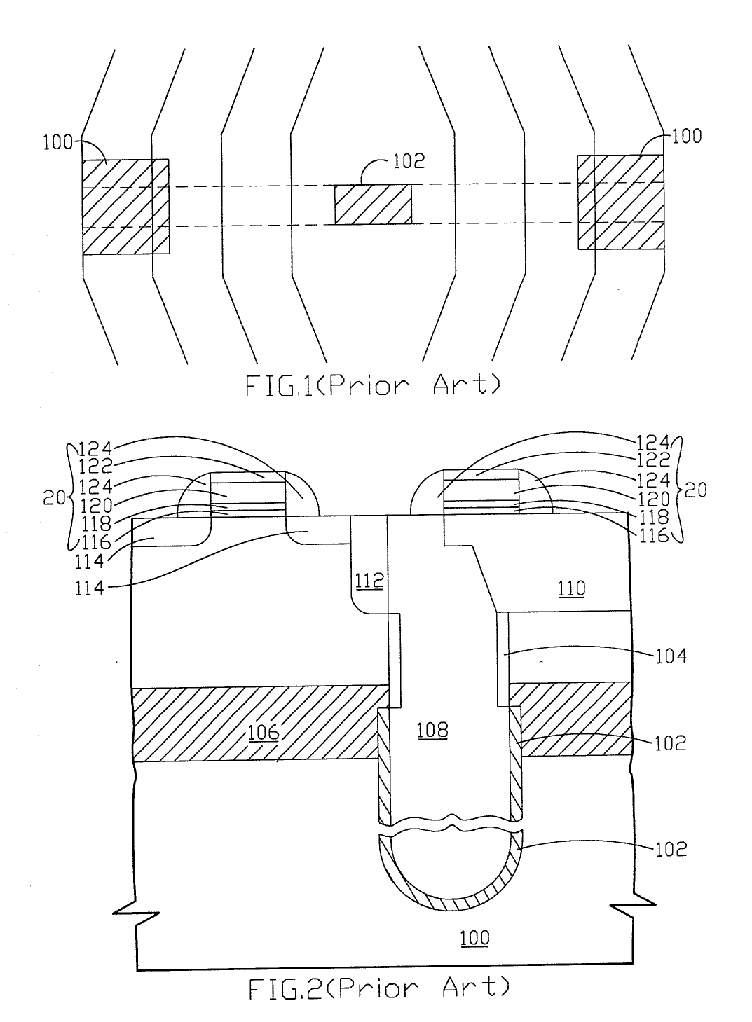

### DESCRIPTION OF THE PREFERRED EMBODIMENT

The semiconductor devices of the present invention are applicable to a broad range of semiconductor devices and can be fabricated from a variety of semiconductor materials. While the invention is described in terms of a single preferred embodiment, those skilled in the art will recognize that many steps described below can be altered without departing from the spirit and scope of the invention.

Furthermore, there is shown a representative portion of a semiconductor structure of the present invention in enlarged, cross-sections of the two dimensional views at several stages of fabrication. The drawings are not necessarily to scale, as the thickness of the various layers are shown for clarity of illustration and should not be interpreted in a limiting sense. Accordingly, these regions will have dimensions, including length, width and depth, when fabricated in an actual device.

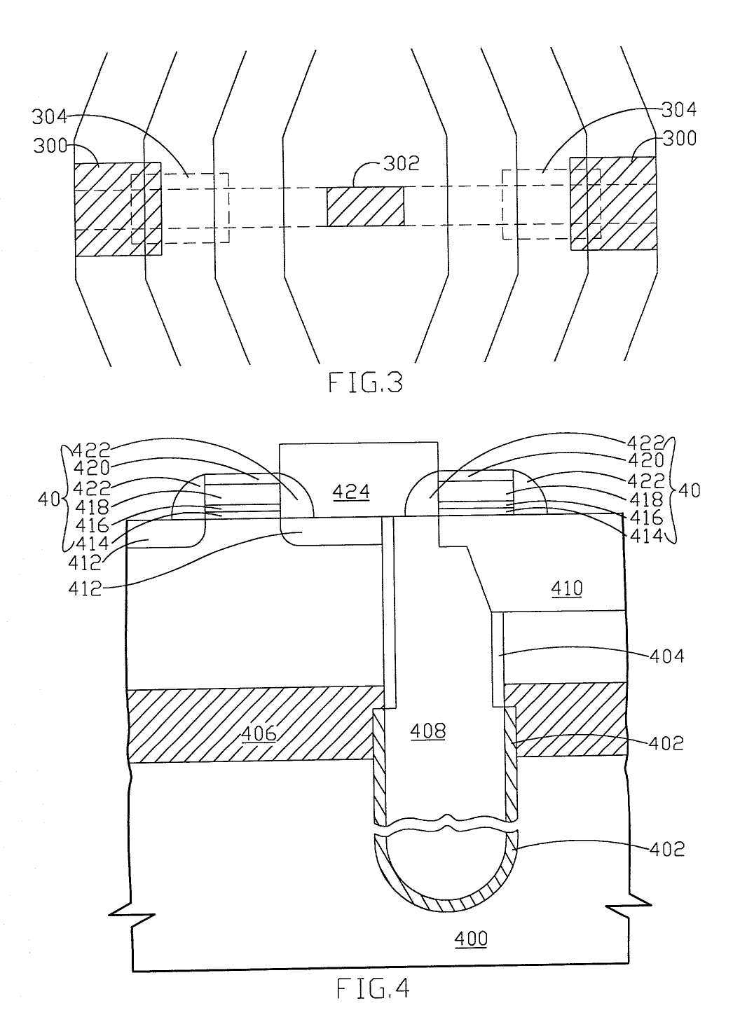

FIG. 3 illustrates a top view of a semiconductor substrate under fabrication as a deep trench DRAM cell in the invention.

FIG. 4 is cross-sectional schematic diagrams illustrating polysilicon connected deep trench DRAM cell in the invention.

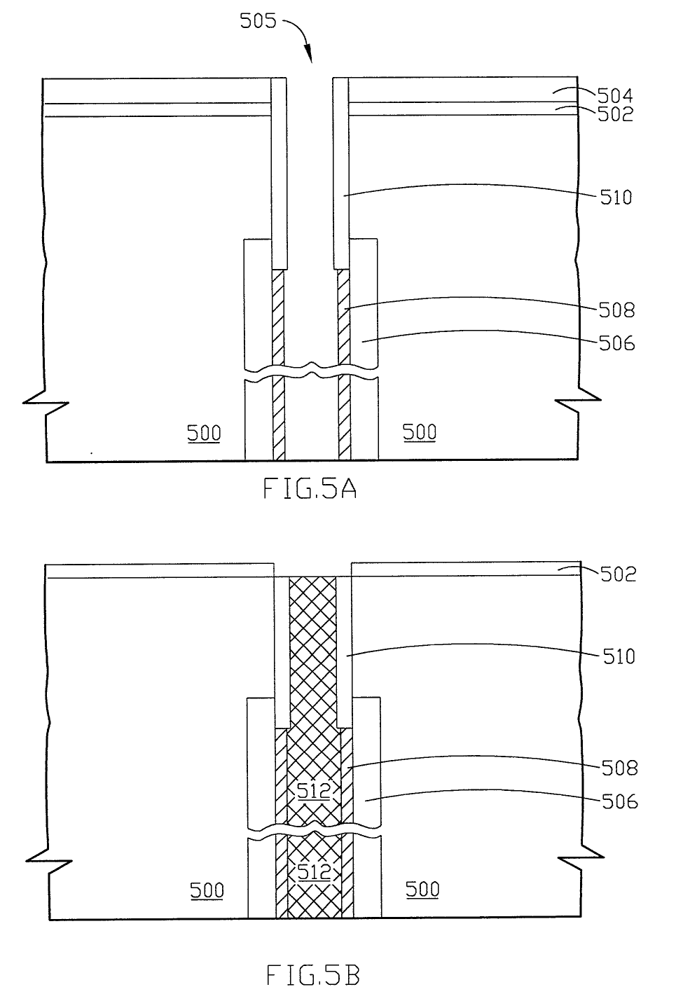

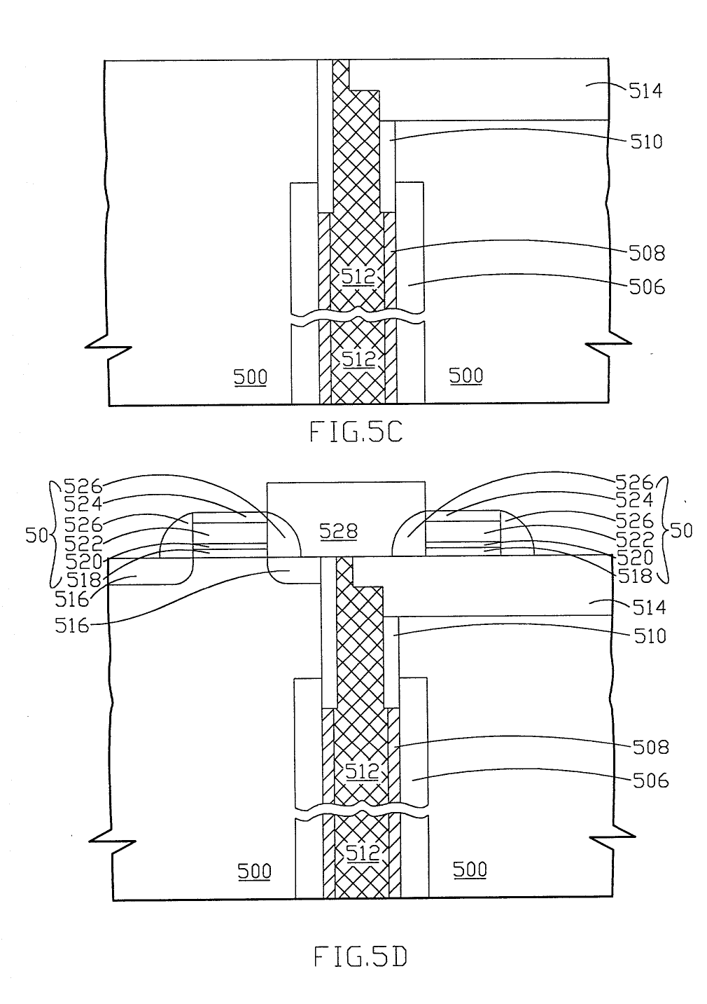

The embodiment of the present invention is depicted in the FIGS. 5A-5D, which show a cross-section of polysilicon connected deep trench DRAM cell in accordance with the present invention.

FIG. 3 illustrates a top view of a semiconductor substrate under fabrication as a deep trench DRAM cell. The top view comprises a deep trench cell 300, bit line 302 and n+ polysilicon layer 304. The n+ polysilicon layer 304 is formed on the deep trench cell 300.

Referring to FIG. 4, a substrate 400 is provided. A deep trench is formed in the substrate 400. A deep trench capacitor is formed at the lower portion of the deep trench. A capacitor dielectric layer 402 is formed on a sidewall of the deep trench at the portion below the capacitor. The capacitor dielectric layer 402 includes, for example, an oxide/nitride/oxide (O/N/O) dielectric layer or an oxide/nitride (O/N) dielectric layer. An oxide collar 404 is formed on a sidewall of the deep trench at the portion above the capacitor. The deep trench capacitor includes a buried plate 406 diffused into the substrate 400. An oxide collar 404 is formed on a sidewall of the deep trench at the portion above the capacitor. A polysilicon layer 408 fills into the deep trench. The polysilicon layer 408 includes a lower portion between the oxide collar 404 and an upper portion which has a contact to the deep trench. However, the adjacent two trench capacitors are necessary to be isolated, usually, by a shallow trench isolation (STI) 410 structure. Formation of the opening conventionally needs another photolithography and etching process. This needs an additional fabrication of photomask and the associated photoresist layer. Then, a gate oxide layer 414 is formed on the substrate 400. Then, the metal-oxide-semiconductor (MOS) transistors 40 are formed on the gate oxide layer 414. The MOS structures 40 have a polysilicon layer 416 on the gate oxide layer 414, a conduction layer 418 on the polysilicon layer 416 and a silicon nitride layer 420 on the conduction layer 418. Then, a spacer 422 is formed on sidewall of the MOS transistors 40. Next, a source/drain region 412 is formed by implanting numerous ions in the substrate 400. Then, a n+ polysilicon layer 424 is formed on the MOS transistor 40.

Referring to FIG. 5A, a substrate 500 is provided. Then, a pad oxide layer 502 is formed on the substrate 500. The pad oxide layer 502 is formed with a thickness between 50 angstroms and 300 angstroms. In the embodiment, thickness of this layer 502 is preferably 110 angstroms. Next, a first mask layer 504 is formed on the pad oxide layer 502. The first mask layer comprises silicon nitride. The first mask layer 504 is formed with a thickness between 1000 angstroms and 3000 angstroms. In the embodiment, thickness of this layer 504 is preferably 2000 angstroms. Then, a second mask layer (not show in figure) is formed on the first mask layer 504. The second mask layer comprises boron silicate glass (BSG). At this current state, the exposed mask layer structure includes the first mask layer 504 and the second mask layer that have different materials. Then, a photoresist layer (not show in figure) is formed on the second mask layer. Next, the second mask layer, the first mask layer 504, the pad oxide layer 502, and the substrate 500 are etched to form an opening under a photoresist opening, wherein a lower portion of the opening in the substrate 500 is a deep trench 505. Next, the photoresist layer and the second mask layer are removed. Then, a buried plate 506 drive in the substrate 500, surrounding a lower portion of the deep trench 505. Then, a capacitor dielectric layer 508 is formed on a sidewall of above the deep trench 505. The capacitor dielectric layer 508 includes, for example, an oxide/nitride/oxide (O/N/O) dielectric layer or an oxide/nitride (O/N) dielectric layer. Next, a dielectric collar layer 510 is formed on a sidewall of the deep trench 505, wherein the dielectric collar layer 510 covers an exposed surface of the capacitor dielectric layer 508 within the deep trench 505 but not fully covers the sidewall of the deep trench 505.

Referring to FIG. 5B, a selective growth polysilicon layer 512 is formed, filling into the deep trench 505 of the opening with a height of the selective growth polysilicon layer 512 higher than the substrate 500 surface. The selective growth polysilicon layer 512 comprises a doped polysilicon layer is deposited, filling into the deep trench, and the polysilicon layer 512 is etched back. Then, the selective growth polysilicon layer 512 is etched to stop on the pad oxide layer 502. Next, the first mask layer 504 is also removed.

Referring to FIG. 5C, the shallow trench isolation (STI) 514 is formed and exposes a portion of the collar dielectric layer 510 at a side originally having contact with the deep trench 505. Next, the shallow trench isolation (STI) structure 514 is formed, filling into a shallow trench isolation (STI) opening. The STI structure 514 is filled into the shallow trench isolation (STI) opening, wherein the STI structure 514 comprises an insulating layer is deposited over the substrate 500 to fill into the shallow trench isolation (STI) opening and a chemical mechanical polishing process is performed. Then, the pad oxide layer 502 is removed.

Referring to FIG. 5D, a gate oxide layer 518 is formed on the substrate 500. Then, a metal-oxide-semiconductor (MOS) transistors 50 are formed on the gate oxide layer 518. The MOS transistors 50 comprises polysilicon layer 518 on the substrate 500, a conductive layer 520 on the polysilicon layer 518 and the silicon nitride layer 522 on the conductive layer 520. Then, a spacer 526 is formed on sidewall of the MOS transistors 50. Next, a source/drain region 516 is formed by implanting numerous ions in the substrate 500. Then, a n+ polysilicon layer 528 is formed on the MOS transistors 50. The n+ polysilicon layer 528 is formed by using a low pressure vapor chemical deposition (LPCVD) method.

While this invention has been described with reference to illustrative embodiments, this description is not intended or to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for forming polysilicon connected deep trench DRAM cell, said method comprising:
providing a substrate, wherein said substrate sequentially has a pad oxide layer thereon, a first mask layer on said pad oxide layer, a second mask layer on said first mask layer, and a photoresist layer on said second mask layer;
etching said second mask layer, said first mask layer, said pad oxide layer, and said substrate to form an opening under a photoresist opening, wherein a lower portion of the opening in said substrate is a deep trench;
removing said photoresist layer and said second mask layer;
driving in a buried plate in said substrate, wherein said buried plate surrounding a lower portion of said deep trench;
forming a capacitor dielectric layer to fill into a lower portion of said deep trench;
forming a dielectric collar layer on a sidewall of said deep trench about said capacitor dielectric layer, wherein said dielectric collar layer covers an exposed surface of said capacitor dielectric layer within said deep trench but not fully covers the sidewall of said deep trench;
forming a selective growth polysilicon layer to fill into said deep trench of said opening;
etching said selective growth polysilicon layer to stop on said pad oxide layer;
forming a shallow trench isolation structure in sidewall of said deep trench;
forming a metal-oxide-semiconductor transistor on said substrate;
forming a spacer on sidewall of said metal-oxide semiconductor transistor;
forming a polysilicon layer on said metal-oxide semiconductor transistor; and
etching back said polysilicon layer.

2. The method for forming polysilicon connected deep trench DRAM cell according to claim 1, wherein said substrate comprises silicon.

3. The method for forming polysilicon connected deep trench DRAM cell according to claim 1, wherein said first mask comprises silicon nitride.

4. The method for forming polysilicon connected deep trench DRAM cell according to claim 1, wherein said second mask layer comprises boron silicate glass (BSG).

5. The method for forming polysilicon connected deep trench DRAM cell according to claim 1, wherein the step of forming the selective growth polysilicon layer comprises:
depositing a doped polysilicon layer, filling into said deep trench; and
etching back said polysilicon layer.

6. The method for forming polysilicon connected deep trench DRAM cell according to claim 1, wherein the step of forming the STI structure, filling into the STI opening comprises:
depositing an insulating layer over the substrate, filling into the STI opening;
performing a chemical mechanical polishing process to polish away the insulating layer; and
removing the pad oxide layer.

7. A method for forming polysilicon connected deep trench DRAM cell, said method comprising:
providing a substrate, wherein said substrate sequentially has a pad oxide layer, a silicon nitride layer, and a boron silicate glass layer;
forming a photoresist layer on said second mask layer;
etching said second mask layer, said first mask layer, said pad oxide layer, and said substrate to form an opening under a photoresist opening, wherein a lower portion of the opening in said substrate is a deep trench;
removing said photoresist layer and said second mask layer;
driving in a buried plate in said substrate, wherein said buried plate surrounding a lower portion of said deep trench;
forming a capacitor dielectric layer to fill into a lower portion of said deep trench;
forming a dielectric collar layer on a sidewall of said deep trench about said capacitor dielectric layer, wherein said dielectric collar layer covers an exposed surface of said capacitor dielectric layer within said deep trench but not fully covers the sidewall of said deep trench;
forming a selective growth polysilicon layer to fill into said deep trench of said opening;
etching said selective growth polysilicon layer to stop on said pad oxide layer;
forming a shallow trench isolation structure in sidewall of said deep trench;
forming a metal-oxide semiconductor transistor on said substrate;
forming a spacer on sidewall of said metal-oxide semiconductor transistor;
forming a polysilicon layer on said metal-oxide semiconductor transistor; and
etching back said polysilicon layer.

8. The method for forming polysilicon connected deep trench DRAM cell according to claim 7, wherein said substrate comprises silicon.

9. The method for forming polysilicon connected deep trench DRAM cell according to claim 7, wherein the step of forming the selective growth polysilicon layer comprises:
depositing a doped polysilicon layer, filling into said deep trench; and
etching back said polysilicon layer.

10. The method for forming polysilicon connected deep trench DRAM cell according to claim 8, wherein the step of forming the STI structure, filling into the STI opening comprises:
depositing an insulating layer over the substrate, filling into the STI opening;
performing a chemical mechanical polishing process to polish away the insulating layer; and
removing the pad oxide layer.
